(19) United States
(12) Patent Application Publication
(10) Pub. No.: US 2023/0088079 A1
(43) Pub. Date: Mar. 23, 2023

(54) SILICON PRECURSORS

(71) Applicant: ENTEGRIS, INC., Billerica, MA (US)

(72) Inventors: SangJin Lee, Suwon-si (KR); MinSeok Ryu, Incheon (KR); Sangbum Han, Norfolk, VA (US); SeongCheol Kim, Suwon-si (KR); YoonHae Kim, Suwon-si (KR); KieJin Park, Suwon-si (KR); YeRim Yeon, Suwon-si (KR); Sungsil Cho, Anyang-si (KR); HwanSoo Kim, Hwaseong-si (KR); JoongKi CHOI, Yongin-si (KR)

(21) Appl. No.: 17/860,177

(22) Filed: Jul. 8, 2022

Related U.S. Application Data
(60) Provisional application No. 63/236,747, filed on Aug. 25, 2021.

(51) Int. Cl. C07F 7/10; H01L 21/02; C23C 16/455

(52) U.S. Cl. CPC C07F 7/10; H01L 21/02219; H01L 21/02532; C23C 16/45553; H01L 21/0214; H01L 21/02126; H01L 21/02164; H01L 21/0217; H01L 21/02167; H01L 21/0262; H01L 21/02271; H01L 21/0228; H01L 21/02274

(57) ABSTRACT

Provided are certain silyl amine compounds useful as precursors in the vapor deposition of silicon-containing materials onto the surfaces of microelectronic devices. Such precursors can be utilized with optional co-reactants to deposit silicon-containing films such as silicon nitride, silicon oxide, silicon oxynitride, silicon oxycarbonitride (SiOCN), silicon carbonitride (SiCN), and silicon carbide.

### TECHNICAL FIELD

The invention relates generally to certain silicon precursor compounds useful in the vapor deposition of silicon-containing films onto microelectronic devices.

### BACKGROUND

Low temperature deposition of silicon-based thin-films is of fundamental importance to current semiconductor device fabrication and processes. For the last several decades, silicon dioxide thin films have been utilized as essential structural components of integrated circuits (ICs), including microprocessor, logic and memory-based devices. Silicon dioxide has been a predominant material in the semiconductor industry and has been employed as an insulating dielectric material for virtually all silicon-based devices that have been commercialized. Silicon dioxide has been used as an interconnect dielectric, a capacitor and a gate dielectric material over the years.

The conventional industry approach for depositing high-purity SiO₂ films has been to utilize tetraethylorthosilicate (TEOS) as a thin-film precursor for vapor deposition of such films. TEOS is a stable, liquid material that has been employed as a silicon source reagent in chemical vapor deposition (CVD), plasma-enhanced chemical vapor deposition (PECVD) and atomic layer deposition (ALD), to achieve high-purity thin-films of SiO₂. Other thin-film deposition methods (e.g., focused ion beam, electron beam and other energetic means for forming thin-films) can also be carried out with this silicon source reagent.

As integrated circuit device dimensions continually decrease, with corresponding advances in lithography scaling methods and shrinkage of device geometries, new deposition materials and processes are correspondingly being sought for forming high integrity SiO₂ thin films. Improved silicon-based precursors (and co-reactants) are desired to form SiO₂ films, as well as other silicon-containing thin films, e.g., Si₃N₄, SiC, and doped SiOₓ high k thin films, that can be deposited at low temperatures, such as temperatures below 400° C. and below 200° C. To achieve these low deposition temperatures, chemical precursors are required to decompose cleanly to yield the desired films.

The achievement of low temperature films also requires the use and development of deposition processes that ensure the formation of homogeneous conformal silicon-containing films. Chemical vapor deposition (CVD) and atomic layer deposition (ALD) processes are therefore being refined and implemented, concurrently with the ongoing search for reactive precursor compounds that are stable in handling, vaporization and transport to the reactor, but exhibit the ability to decompose cleanly at low temperatures to form the desired thin films. The fundamental challenge in this effort is to achieve a balance of precursor thermal stability and precursor suitability for high-purity, low temperature film growth processes, while maintaining the desired electronic and mechanical properties of the films thus produced.

### SUMMARY

The invention provides certain silylamine compounds, which are believed to be useful as precursors in the deposition of silicon-containing films onto microelectronic device substrates. In particular, the invention provides a vapor deposition process which utilizes compounds of Formula (I):

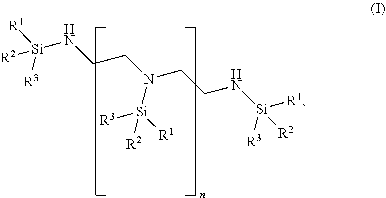

wherein R¹, R², and R³ are each independently chosen from hydrogen, C₁-C₁₀ alkyl, C₃-C₈ cycloalkyl, aryl, and benzyl and n is 0, 1, or 2.

In this deposition process, exemplary compounds of Formula (I) include trimethylsilylethylene triamine and trimethylsilylethylene diamine.

### BRIEF DESCRIPTION OF THE DRAWINGS

FIG. 1 is a ¹H NMR of trimethylsilyldiethylene triamine, i.e., the compound of Formula (I), wherein each of R¹, R², and R³ is methyl.

FIG. 2 is a Differential Scanning Calorimetry analysis (DSC) of trimethylsilyldiethylene triamine.

FIG. 3 is a thermogravimetric analysis (TGA) of trimethylsilyldiethylene triamine. This data shows good thermal stability, high volatility with a nil residue. In this graph, T50 is the temperature at 50% weight loss; measured T50 was 156.84° C.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a compound of Formula (I):

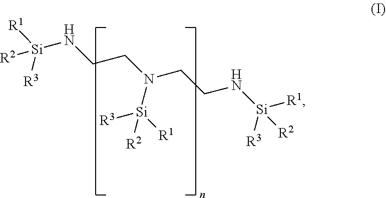

wherein R¹, R², and R³ are each independently chosen from hydrogen, C₁-C₁₀ alkyl, C₃-C₈ cycloalkyl, aryl, and benzyl and n is 0, 1, or 2, provided that when n is 1, the compound of Formula (I) is other than trimethylsilylethylene triamine.

In the case of n=0, the compound of Formula (I) will be as follows:

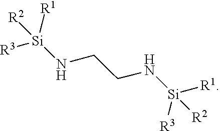

In the case of n=1, the compound of Formula (I) will be as follows:

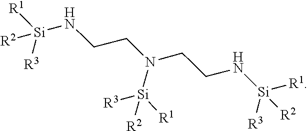

The compounds of Formula (I) can be prepared by contacting a compound of the Formula (A):

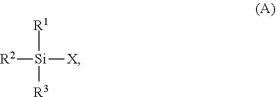

wherein X is halo,
with a compound of the Formula (B),

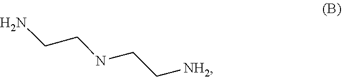

in the presence of a base.

In the above process, X can be chosen from chloro, bromo, iodo, or fluoro.

As used herein, the term “C₁-C₁₀ alkyl” refers to aliphatic hydrocarbon groups having from one to ten carbon atoms. Exemplary groups include methyl, ethyl, n-propyl, isopropyl, n-butyl, t-butyl, sec-butyl, pentyl, hexyl, heptyl, octyl, nonyl, decyl, and the like.

As used herein, the term “C₃-C₈ cycloalkyl” refers to cycloaliphatic groups having from three to ten carbon atoms and includes groups such as cyclopropyl, cyclobutyl, cyclopentyl, cyclohexyl, cycloheptyl, and cyclooctyl.

As used herein, the term “aryl” refers to aromatic rings which are comprised of only carbon and hydrogen. Exemplary groups include phenyl, biphenyl, napthyl, and the like.

Bases useful in this process include those bases which are sufficiently strong to deprotonate the amine group(s) on the compound of Formula (B) to enable displacement of the halogen atom on the compound of Formula (A), i.e., compounds typically used in organic synthesis as non-nucleophilic bases. In this regard, exemplary bases include triethylamine, pyrrolidine, tetramethylguanidine, 1,4-diazabicyclo[2.2.2]octane (DABCO), 1,5-dizabicyclo[4.3.0]non-5-ene (CAS No. 3001-72-7, also known as “DBN”), 4-dimethylaminopyridine (CAS No. 1122-58-3, also known as “DMAP”), 1,5,7-triazabicyclo[4.4.0]dec-5-ene (CAS No. 5807-14-7, also known as “TBD”), and 1,8-diazabicyclo[5.4.0]undec-7-ene (CAS No. 6674-22-2, also known as “DBU”).

The process can be conducted utilizing a suitable polar aprotic solvent which does not interfere with the reaction, such as tetrahydrofuran, diethyl ether, toluene, or dichloromethane. In general, the silicon-containing compound (A) is combined with a base as described herein and then the amine compound (B) is added to the reaction mixture, for example, at room temperature. Once the reaction is complete, a solid by-product can be removed via filtration and the remaining filtrate purified by fractional distillation to form a colorless liquid product (I).

The compounds of Formula (I) are believed to be useful as precursors in the vapor deposition of silicon-containing films and, in particular, films on the surface(s) of microelectronic devices. In certain embodiments, the films also contain nitrogen and/or oxygen and/or carbon.

As used herein, the term “silicon-containing film” refers to films such as silicon dioxide, silicon nitride, silicon oxynitride, silicon carbide, silicon carbonitride, silicon oxycarbonitride, low-k thin silicon-containing films, high-k gate silicate films and low temperature silicon epitaxial films.

Accordingly, the compounds of Formula (I) above can be employed for forming high-purity thin silicon-containing films by any suitable vapor deposition technique, such as chemical vapor deposition (CVD), digital (pulsed) CVD, atomic layer deposition (ALD), pulsed plasma processes, plasma enhanced cyclical chemical vapor deposition (PECCVD), a flowable chemical vapor deposition (FCVD), or a plasma-enhanced ALD-like process. In certain embodiments, such vapor deposition processes can be utilized to form silicon-containing films on microelectronic devices to form films having a thickness of from about 20 angstroms to about 2000 angstroms.

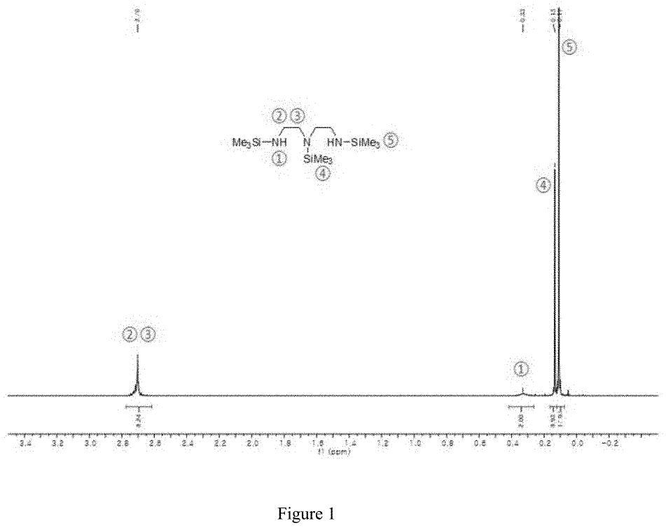

FIG. 1 is a ¹H NMR of trimethylsilyldiethylene triamine, i.e., the compound of Formula (I), wherein each of R¹, R², and R³ is methyl.

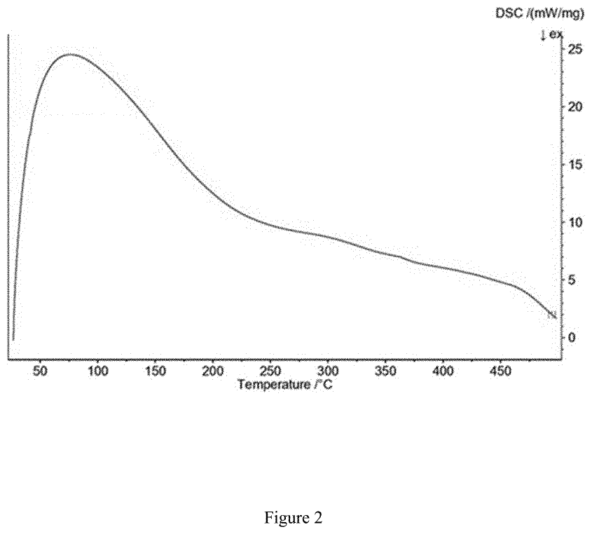

FIG. 2 is a Differential Scanning Calorimetry analysis (DSC) of trimethylsilyldiethylene triamine.

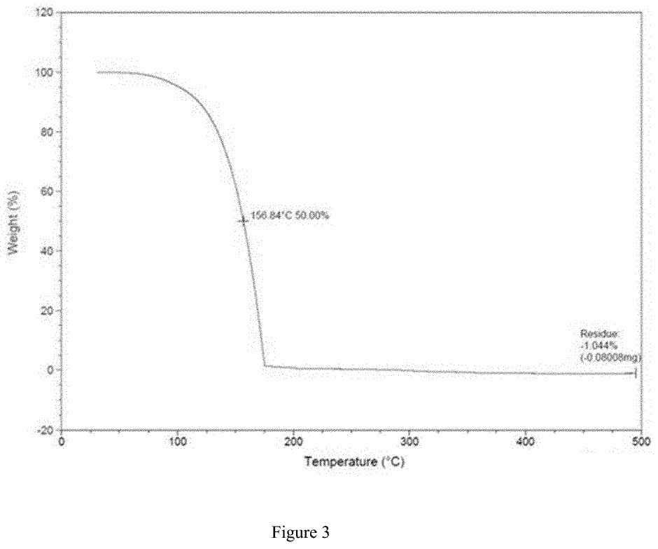

FIG. 3 is a thermogravimetric analysis (TGA) of trimethylsilyldiethylene triamine. This data shows good thermal stability, high volatility with a nil residue. In this graph, T50 is the temperature at 50% weight loss; measured T50 was 156.84° C.

In the process of the invention, the compounds above may be reacted with the desired microelectronic device substrate in any suitable manner, for example, in a single wafer CVD, ALD and/or PECVD or PEALD chamber (i.e., “reaction zone”), or in a furnace containing multiple wafers.

Alternatively, the process of the invention can be conducted as an ALD or ALD-like process. As used herein, the terms “ALD or ALD-like” refer to processes such as (i) each reactant including the silicon precursor compound of Formula (I) and an oxidizing or reducing gas is introduced sequentially into a reactor such as a single wafer ALD reactor, semi-batch ALD reactor, or batch furnace ALD reactor, or (ii) each reactant, including the silicon precursor compound of Formula (I) and an oxidizing or reducing gas is exposed to the substrate or microelectronic device surface by moving or rotating the substrate to different sections of the reactor and each section is separated by an inert gas curtain, i.e., spatial ALD reactor or roll to roll ALD reactor.

In one embodiment, the vapor deposition conditions comprise a temperature of about room temperature (e.g., about 23° C.) to about 1000° C., or about 100° C. to about 1000° C., or about 450° C. to about 1000° C., and a pressure of about 0.5 to about 1000 Torr. In another embodiment, the vapor deposition conditions comprise a temperature of about 100° C. to about 800° C., or about 500° C. to about 750° C.

In general, the desired film produced using the precursor compounds of Formula (I) can be tailored by choice of each compound, coupled with the utilization of reducing or oxidizing co-reactants. See, for example, the following Scheme 1 which illustrates how the precursors of Formula (I) may be utilized in vapor deposition processes:

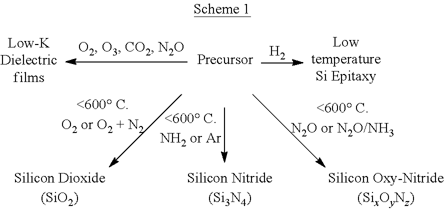

In one embodiment, the vapor deposition processes may further comprise a step involving exposing the precursor to a gas such as H₂, H₂ plasma, H₂/O₂ mixtures, water, N₂O, N₂O plasma, NH₃, NH₃ plasma, N₂, or N₂ plasma. For example, an oxidizing gas such as O₂, O₃, N₂O, water vapor, alcohols or oxygen plasma may be used. In one embodiment, the precursor of Formula (I) is utilized in an ALD process with O₃ as the oxidizing gas. In certain embodiments, the oxidizing gas further comprises an inert gas such as argon, helium, nitrogen, or a combination thereof. In another embodiment, the oxidizing gas further comprises nitrogen, which can react with the precursors of Formula (I) under plasma conditions to form silicon oxynitride films.

Accordingly, in a further aspect, the invention provides a process for depositing a silicon-containing film on a microelectronic device substrate, which comprises contacting the substrate with compound of Formula (I):

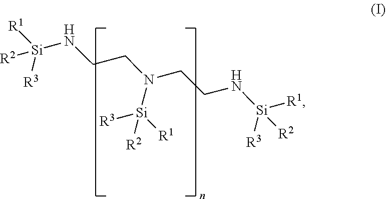

wherein R¹, R², and R³ are each independently chosen from hydrogen, C₁-C₁₀ alkyl, C₃-C₈ cycloalkyl, aryl, and benzyl and n is 0, 1, or 2, in a reaction zone, under vapor deposition conditions.

In certain embodiments, the process of this aspect will comprise the use of one or more co-reactants chosen from oxidizing gases, reducing gases, and hydrocarbons.

In another embodiment, the vapor deposition processes above may further comprise a step involving exposing the film to a reducing gas. In certain embodiments of the present invention, the reducing gas is comprised of gases chosen from H₂, hydrazine (N₂H₄), methyl hydrazine, t-butyl hydrazine, 1,1-dimethylhydrazine, 1,2-dimethylhydrazine, and NH₃. In the case of such nitrogen containing reducing gases, a vapor deposition technique such as atomic layer deposition can be utilized to form a material comprising silicon and nitrogen

The compounds of Formula (I) are believed to be capable of low-temperature PECVD and/or PEALD formation of silicon-containing films as well as high temperature ALD. Such compounds exhibit high volatility and chemical reactivity but are stable with respect to thermal degradation at temperatures involved in the volatilization or vaporization of the precursor, allowing consistent and repeatable transport of the resulting precursor vapor to the deposition zone or reaction chamber.

While using the precursor compounds of Formula (I), the incorporation of carbon into such films may be accomplished by utilization of co-reactants such as carbon in the form of methane, ethane, ethylene or acetylene for example, to further introduce carbon content into the silicon-containing films, thereby producing silicon carbide.

The deposition methods disclosed herein may involve one or more purge gases and/or carrier gases. A purge gas is used to purge away unconsumed reactants and/or reaction by-products, and is an inert gas that does not react with the precursors. Exemplary purge gases include, but are not limited to, argon, nitrogen, helium, neon, hydrogen, and mixtures thereof. In certain embodiments, a purge gas such as Ar is supplied into the reactor at a flow rate ranging from about 10 to about 2000 seem for about 0.1 to 1000 seconds, thereby purging the unreacted material and any byproduct that may remain in the reactor.

The respective step of supplying the silicon precursor compounds, oxidizing gas, reducing gas, and/or other precursors, source gases, and/or reagents may be performed by changing the sequences for supplying them and/or changing the stoichiometric composition of the resulting dielectric film.

Energy is applied to the at least one of the silicon precursor compounds of Formula (I) and oxidizing gas, reducing gas, or combination thereof to induce reaction and to form the silicon-containing film on the microelectronic device substrate. Such energy can be provided by, but not limited to, thermal, pulsed thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated ‘remotely’ of the reaction zone and substrate, being supplied into the reactor.

As used herein, the term “microelectronic device” corresponds to semiconductor substrates, including 3D NAND structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that includes a negative channel metal oxide semiconductor (nMOS) and/or a positive channel metal oxide semiconductor (pMOS) transistor and will eventually become a microelectronic device or microelectronic assembly. Such microelectronic devices contain at least one substrate, which can be chosen from, for example, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

In atomic layer deposition, sequential processing steps are generally referred to as “pulses” or cycles. As such, ALD processes are based on controlled, self-limiting surface reactions of precursor chemicals. Gas phase reactions are avoided by alternately and sequentially contacting the substrate with the precursors. Vapor phase reactants are separated from each other in time and on the substrate surface, for example, by removing excess reactants and/or reactant by-products from the reaction chamber between reactant pulses. In some embodiments, one or more substrate surfaces are alternately and sequentially contacted with two or more vapor phase precursors, or reactants. Contacting a substrate surface with a vapor-phase reactant means that the reactant vapor is in contact with the substrate surface for a limited period of time in the reaction zone. In other words, it can be understood that the substrate surface is exposed to each vapor phase reactant for a limited period of time.

In certain embodiments, the pulse time (i.e., duration of precursor exposure to the substrate) for the precursor compounds depicted above ranges between about 1 and 30 seconds. When a purge step is utilized, the duration is from about 1 to 20 seconds or 1 to 30 seconds. In other embodiments, the pulse time for the co-reactant ranges from 5 to 60 seconds.

By way of example, in the case of atomic layer deposition (ALD), the compound of Formula (I) can be utilized as one “silicon” precursor, and in the case of a desired silicon-nitride film, may utilize a nitrogen-containing material as a co-reactant or as another precursor. The nitrogen-containing material may be organic (for instance, t-butyl hydrazine), or inorganic (for instance, NH₃). In certain embodiments, ALD may be used to form material comprising silicon and nitrogen. Such material may comprise, consist essentially of, or consist of silicon nitride, and/or may have other components, depending on the co-reactants chosen in a particular case.

Briefly, a substrate comprising at least one surface can be heated to a suitable deposition temperature, for example ranging from 150° C. to 700° C., generally at pressures of, for example, from about 0.5 to 50 torr. In other embodiments, the temperature is from about 200° C. to 300° C. or 500° C. to 650° C. Deposition temperatures are generally maintained below the thermal decomposition temperature of the reactants but at a high enough temperature to avoid condensation of reactants and to provide the activation energy for the desired “selective” surface reactions.

The surface of the substrate is contacted with a vapor phase first reactant. In certain embodiments, a pulse of vapor phase first reactant is provided to a reaction zone containing the substrate. In other embodiments, the substrate is moved to a reaction space containing vapor phase first reactant. Conditions are generally selected such that no more than about one monolayer of the first reactant is adsorbed on the substrate surface in a self-limiting manner. The appropriate contacting times can be readily determined by the skilled artisan based on the particular conditions, substrates and reactor configurations. Excess first reactant and reaction by-products, if any, are removed from the substrate surface, such as by purging with an inert gas or by removing the substrate from the presence of the first reactant. Purging means that vapor phase precursors and/or vapor phase by-products are removed from the substrate surface such as by evacuating a chamber with a vacuum pump and/or by replacing the gas inside a reactor with an inert gas such as argon or nitrogen. In certain embodiments, purging times are from about 0.05 to 20 seconds, between about 1 and 10, or between about 1 and 2 seconds. However, other purge times can be utilized if necessary, such as where highly conformal step coverage over extremely high aspect ratio structures or other structures with complex surface morphology is needed.

The surface of the substrate can then be contacted with a vapor phase second gaseous reactant, i.e., a second precursor or a co-reactant such as an oxidizing or reducing gas. In certain embodiments a pulse of a second gaseous reactant is provided to a reaction space containing the substrate. In other embodiments the substrate is moved to a reaction space containing the vapor phase second reactant. Excess second reactant and gaseous by-products of the surface reaction, if any, are removed from the substrate surface. The steps of contacting and removing are repeated until a thin film of the desired thickness has been selectively formed on the first surface of substrate, with each cycle leaving generally no more than about a molecular monolayer. Additional phases comprising alternately and sequentially contacting the surface of a substrate with other reactants can be included to form more complicated materials, such as ternary materials.

Each phase of each cycle is generally self-limiting. An excess of reactant precursors is supplied in each phase to saturate the susceptible structure surfaces. Surface saturation ensures reactant occupation of all available reactive sites (subject, for example, to physical size or “steric hindrance” restraints) and thus ensures excellent step coverage. Typically, less than one molecular layer of material is deposited with each cycle, however, in some embodiments more than one molecular layer is deposited during the cycle.

Removing excess reactants can include evacuating some of the contents of a reaction zone and/or purging a reaction zone with helium, nitrogen or another inert gas. In certain embodiments, purging can comprise turning off the flow of the reactive gas while continuing to flow an inert carrier gas to the reaction space. In another embodiment, the purge step may employ a vacuum step to remove excess reactant from the surface.

Reactors capable of being used to grow such thin films can be used for the deposition described herein. Such reactors include ALD reactors, as well as CVD reactors equipped with appropriate equipment and means for providing the precursors in a “pulsed” manner. According to certain embodiments, a showerhead reactor may be used. Examples of suitable reactors that may be used include commercially available equipment, as well as home-built reactors, and will be known to those skilled in the art of CVD and/or ALD.

Exemplary compounds of Formula (I) include those illustrated in the following Table:

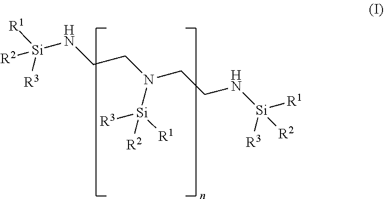

| R¹ | R² | R³ | n |
|---|---|---|---|
| methyl | methyl | methyl | 0 |
| methyl | methyl | methyl | 1 |
| methyl | methyl | methyl | 2 |
| ethyl | ethyl | ethyl | 0 |
| ethyl | ethyl | ethyl | 1 |
| ethyl | ethyl | ethyl | 2 |
| n-propyl | n-propyl | n-propyl | 0 |
| n-propyl | n-propyl | n-propyl | 1 |
| n-propyl | n-propyl | n-propyl | 2 |
| hydrogen | hydrogen | hydrogen | 0 |
| hydrogen | hydrogen | hydrogen | 1 |
| hydrogen | hydrogen | hydrogen | 2 |
| isopropyl | isopropyl | isopropyl | 0 |
| isopropyl | isopropyl | isopropyl | 1 |
| isopropyl | isopropyl | isopropyl | 2 |
| n-butyl | n-butyl | n-butyl | 0 |
| n-butyl | n-butyl | n-butyl | 1 |
| n-butyl | n-butyl | n-butyl | 2 |

### EXAMPLES

### Example 1—Trimethylsilylethylene Triamine

A mixture of trimethylsilyl chloride (50.0 g, 0.41 mol) and the bicyclic amidine base (DBU) (63.06 g, 0.41 mol) in diethylether (500 mL) was stirred for an hour at room temperature under nitrogen atmosphere. To this reaction mixture, diethylenetriamine (14.24 g, 0.14 mol) was added and stirred for 12 hours. After 12 hours of stirring, a white precipitate obtained during the reaction was filtered off and the filtrate was collected. The filtrate was further filtered through a syringe filter (0.45 m). After filtration, the crude product was purified by fractional distillation to yield the title product as a colorless liquid (53.5% yield). The crude product was vacuum distilled at 0.8 Torr using short path distillation. A forecut from 40° C. to 60° C. was discarded and the main fraction boiling at 92° C. was collected. The mass of the colorless oil in the main fraction (99.3% by GC-FID) was 160 g (55% yield). ¹H NMR (C₆D₆): δ 2.70 (br, 8H, CH2); 0.33 (br, 2H, NH); 0.13 (s, 9H, Si(CH₃)3); 0.11 (s, 18H, Si(CH₃)3) ppm

Aspects

In a first aspect, the invention provides a compound of Formula (I):

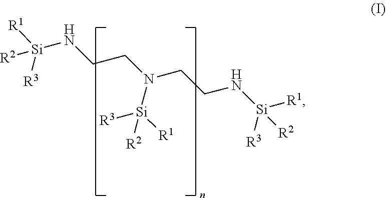

wherein R¹, R², and R³ are each independently chosen from hydrogen, C₁-C₁₀ alkyl, C₃-C₈ cycloalkyl, aryl, and benzyl and n is 0, 1, or 2, provided that when n is 1, the compound of Formula (I) is other than trimethylsilylethylene triamine.

In a second aspect, the invention provides the first aspect, wherein n is 0.

In a third aspect, the invention provides the first aspect, wherein n is 1.

In a fourth aspect, the invention provides the first, second, or third aspects, wherein each of R¹, R², and R³ is chosen from methyl, ethyl, n-propyl, isopropyl, n-butyl, sec-butyl, and tert-butyl.

In a fifth aspect, the invention provides any one of the first through fourth aspects, wherein each of R¹, R², and R³ are methyl.

In a sixth aspect, the invention provides any one of the first through fourth aspects, wherein each of R¹, R², and R³ are hydrogen.

In a seventh aspect, the invention provides the compound of claim 1, having the formula

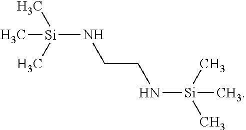

In an eighth aspect, the invention provides a process for depositing a silicon-containing film on a microelectronic device substrate, which comprises contacting the substrate with compound of Formula (I):

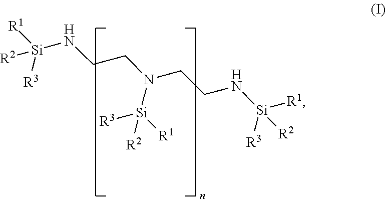

wherein R¹, R², and R³ are each independently chosen from hydrogen, C₁-C₁₀ alkyl, C₃-C₁₀ cycloalkyl, C₃-C₁₀ alkenyl, C₃-C₁₀ alkynyl, aryl, and heteroaryl, and n is 0, 1, or 2, in a reaction zone, under vapor deposition conditions.

In a ninth aspect, the invention provides the process of the eighth aspect, wherein n is 0.

In a tenth aspect, the invention provides the process of the eighth aspect, wherein n is 1.

In an eleventh aspect, the invention provides the process of the eighth, ninth, or tenth aspects, wherein each of R¹, R², and R³ is chosen from methyl, ethyl, n-propyl, isopropyl, n-butyl, sec-butyl, and tert-butyl.

In a twelfth aspect, the invention provides the process of any one of the eighth through eleventh aspects, wherein each of R¹, R², and R³ are methyl.

In a thirteenth aspect, the invention provides the process of any one of the eighth through eleventh aspects, wherein each of R¹, R², and R³ are hydrogen.

In a fourteenth aspect, the invention provides the process of any one of the eighth through the eleventh aspects, wherein the compound of Formula (I) is

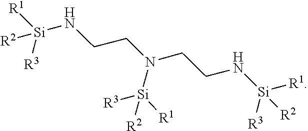

In a fifteenth aspect, the invention provides the process of any one of the eighth trough the eleventh aspects, wherein the compound of Formula (I) is

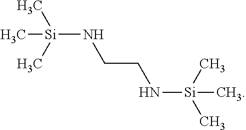

In a sixteenth aspect, the invention provides a process for preparing a compound of Formula (I):

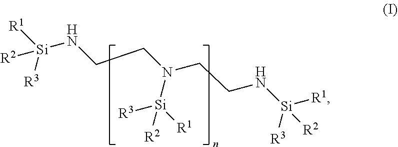

wherein R¹, R², and R³ are each independently chosen from hydrogen, C₁-C₁₀ alkyl, C₃-C₈ cycloalkyl, aryl, and benzyl and n is 0, 1, or 2;
which comprises contacting a compound of the Formula (A):

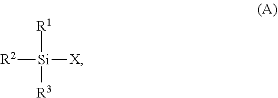

wherein X is halo,
with a compound of the Formula (B),

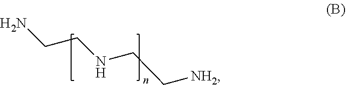

in the presence of a base.

In a seventeenth aspect, the invention provides the process of the sixteenth aspect, wherein n is 0.

In an eighteenth aspect, the invention provides the process of the sixteenth aspect, wherein n is 1.

In a nineteenth aspect, the invention provides the process of sixteenth aspect, wherein the compound of Formula (I) has the formula:

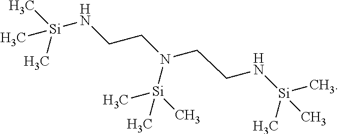 [SMILES: C[Si](C)(C)NCCN(CCN[Si](C)(C)C)[Si](C)(C)C]

In a twentieth aspect, the invention provides the process of the sixteenth aspect, wherein the compound of Formula (I) has the formula:

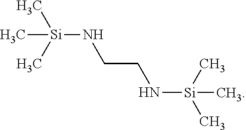

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A compound of Formula (I): 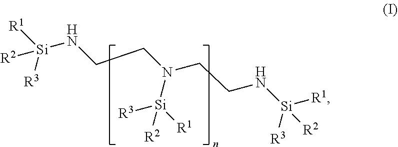
wherein R¹, R², and R³ are each independently chosen from hydrogen, C₁-C₁₀ alkyl, C₃-C₈ cycloalkyl, aryl, and benzyl and n is 0, 1, or 2, provided that when n is 1, the compound of Formula (I) is other than trimethylsilylethylene triamine.

2. The compound of claim 1, wherein n is 0.

3. The compound of claim 1, wherein n is 1.

4. The compound of claim 1, wherein each of R¹, R², and R³ is chosen from methyl, ethyl, n-propyl, isopropyl, n-butyl, sec-butyl, and tert-butyl.

5. The compound of claim 1, wherein each of R¹, R², and R³ are methyl.

6. The compound of claim 1, wherein each of R¹, R², and R³ are hydrogen.

7. The compound of claim 1, having the formula

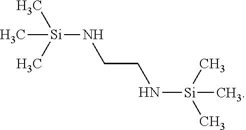

8. A process for depositing a silicon-containing film on a microelectronic device substrate, which comprises contacting the substrate with compound of Formula (I): 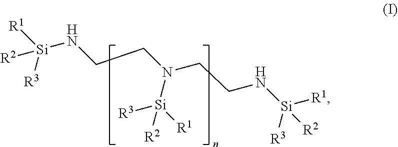
wherein R¹, R², and R³ are each independently chosen from hydrogen, C₁-C₁₀ alkyl, C₃-C₈ cycloalkyl, aryl, and benzyl and n is 0, 1, or 2, in a reaction zone, under vapor deposition conditions.

9. The process of claim 8, wherein n is 0.

10. The process of claim 8, wherein n is 1.

11. The process of claim 8, wherein each of R¹, R², and R³ is chosen from methyl, ethyl, n-propyl, isopropyl, n-butyl, sec-butyl, and tert-butyl.

12. The process of claim 8, wherein each of R¹, R², and R³ are methyl.

13. The process of claim 8, wherein each of R¹, R², and R³ are hydrogen.

14. The process of claim 8, wherein the compound of Formula (I) is

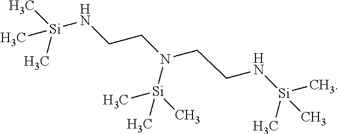 [SMILES: C[Si](C)(C)NCCN(CCN[Si](C)(C)C)[Si](C)(C)C]

15. The process of claim 8, wherein the compound of Formula (I) is

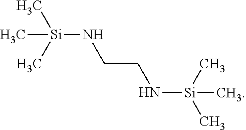

16. A process for preparing a compound of Formula (I): 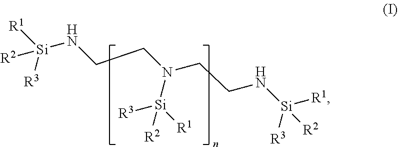
wherein R¹, R², and R³ are each independently chosen from hydrogen, C₁-C₁₀ alkyl, C₃-C₈ cycloalkyl, aryl, and benzyl and n is 0, 1, or 2;
which comprises contacting a compound of the Formula (A): 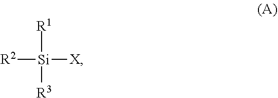
wherein X is halo,
with a compound of the Formula (B), 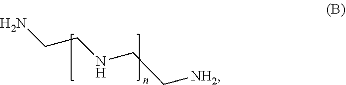
in the presence of a base.

17. The process of claim 16, wherein n is 0.

18. The process of claim 16, wherein n is 1.

19. The process of claim 16, wherein the compound of Formula (I) has the formula:

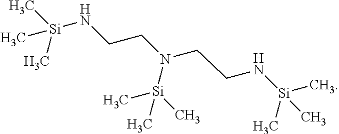 [SMILES: C[Si](C)(C)NCCN(CCN[Si](C)(C)C)[Si](C)(C)C]

20. The process of claim 16, wherein the compound of Formula (I) has the formula: [chemical structure]
